(19) United States
(12) Patent Application Publication
(10) Pub. No.: US 2015/0091661 A1
(43) Pub. Date: Apr. 2, 2015

(54) ATOMIC OSCILLATOR, FREQUENCY ADJUSTING METHOD OF ATOMIC OSCILLATOR, ELECTRONIC APPARATUS, AND MOVING OBJECT

(71) Applicant: Seiko Epson Corporation, Tokyo (JP)

(72) Inventors: Koji CHINDO, Suwa (JP); Noriaki TANAKA, Chino (JP); Tomohiro TAMURA, Suwa (JP); Hiroyuki YOSHIDA, Suwa (JP); Yoshiyuki MAKI, Suwa (JP)

(21) Appl. No.: 14/499,623

(22) Filed: Sep. 29, 2014

(30) Foreign Application Priority Data
Sep. 30, 2013 (JP) 2013-205753

(51) Int. Cl. H03B 17/00

(52) U.S. Cl. CPC H03B 17/00
USPC 331/94.1

(57) ABSTRACT

An atomic oscillator includes a gas cell into which a metal atom and a buffer gas are sealed, a light source that emits light for exciting the metal atom in the gas cell, and a light detection unit (light reception unit) that detects the light which has been transmitted through the gas cell, in which the buffer gas includes neon (Ne) and argon (Ar), and a pressure ratio of Ar to the total of Ne and Ar is greater than 0 and less than 0.5.

### BACKGROUND

1. Technical Field

The present invention relates to an atomic oscillator, a frequency adjusting method of an atomic oscillator, an electronic apparatus, and a moving object.

2. Related Art

In the related art, an atomic oscillator is known as an oscillation source which oscillates at a reference frequency.

In the atomic oscillator, a gas cell in which a gaseous alkali metal atom is sealed is irradiated with excitation light, and a reference frequency is obtained by observing light transmitted therethrough.

For example, in an atomic oscillator using a quantum interference effect (also referred to as coherent population trapping (CPT)) caused by two types of resonance light beams (excitation light beams) 1 and 2 with different wavelengths, when an alkali metal is irradiated with the resonance light beams 1 and 2, light absorptance (light transmittance) of the resonance light beams 1 and 2 in the alkali metal varies depending on a difference (ω₁−ω₂) between a frequency ω₁ of the resonance light 1 and a frequency ω₂ of the resonance light 2. In addition, when the difference ω₁−ω₂) between the frequency ω₁ of the resonance light 1 and the frequency ω₂ of the resonance light 2 matches a frequency ω₀ corresponding to an energy difference between the ground state 1 and the ground state 2, excitation from the ground states 1 and 2 to the excited state stops, respectively. At this time, neither of the resonance light beams 1 and 2 is absorbed by the alkali metal, but both are transmitted therethrough. For this reason, the intensity of the light transmitted through the gas cell rapidly increases, and this rapidly increasing signal is detected as an EIT signal. The EIT signal has an inherent value which is defined by the kind of alkali metal, and therefore such an EIT signal can be used as a reference frequency.

However, the EIT signal has an inherent value defined depending on the kind of the alkali metal, but a gaseous alkali metal atom undergoes thermal motion, thus ideal quantum interference hardly ever occurs due to the influence of the thermal motion, and therefore a spectral width increases.

Accordingly, a method has been proposed in which a buffer gas such as He, Ne, and Ar are sealed into a gas cell so as to reduce thermal motion, and thus a spectral width of an EIT signal does not increase. However, in this method, that is, in a configuration in which the buffer gas is sealed into the gas cell, a temperature characteristic appears in which an EIT signal (an inherent value defined depending on the kind of alkali metal) is shifted due to a temperature variation in the gas cell.

For this reason, in order to prevent the EIT signal from being shifted, a method is employed in which two kinds of buffer gases which cancel out the mutual temperature characteristics in which an EIT signal is shifted are mixed at a predetermined mixture ratio in the gas cell.

For example, JP-A-2010-245805 discloses a method in which Ne and Ar as buffer gases are mixed at a mixture ratio (gas ratio) of 1:1 in the gas cell on the basis of the fact that, in a case where a Cs gas is sealed into a gas cell as an alkali metal gas, if Ne is sealed alone as a buffer gas, an EIT signal is shifted with a temperature characteristic of +3 Hz/° C., and if Ar is sealed alone as a buffer gas, an EIT signal is shifted with a temperature characteristic of −3 Hz/° C. (refer to FIG. 2 of JP-A-2010-245805).

However, according to another examination conducted by the present inventor, if Ne is sealed alone as a buffer gas, an EIT signal is shifted with a temperature characteristic of +3 Hz/° C., and if Ar is sealed alone as a buffer gas, an EIT signal is shifted with a temperature characteristic of −3 Hz/° C., but it has been found that deviation occurs in the temperature characteristics in which the EIT signal is shifted. Particularly, it has been found that the tendency for the deviation to occur is higher when an atomic oscillator (gas cell) is made small-sized.

### SUMMARY

An advantage of some aspects of the invention is to provide an atomic oscillator having a high accuracy reference frequency without being influenced by a temperature variation in a gas cell, a frequency adjusting method of the atomic oscillator, for obtaining the atomic oscillator, and an electronic apparatus and a moving object including the atomic oscillator.

The invention can be implemented as the following forms or application examples.

### APPLICATION EXAMPLE 1

This application example is directed to an atomic oscillator including: a gas cell into which a metal atom and a buffer gas are sealed; a light source that emits light for exciting the metal atom in the gas cell; and a light reception unit that detects the light which has been transmitted through the gas cell, in which the buffer gas includes neon (Ne) and argon (Ar), and a pressure ratio of Ar to the total of Ne and Ar is greater than 0 and less than 0.5.

With this configuration, it is possible to provide the atomic oscillator having a high accuracy reference frequency without being influenced by a temperature variation in the gas cell.

### APPLICATION EXAMPLE 2

In the atomic oscillator according to the application example described above, it is preferable that the metal atom includes a cesium (Cs).

When cesium (Cs) is included as an alkali metal, if a pressure ratio of Ar to the total of Ne and Ar is set to be in the range, it is possible to more appropriately minimize or prevent shift of an EIT signal due to a temperature variation in the gas cell.

### APPLICATION EXAMPLE 3

In the atomic oscillator according to the application example described above, it is preferable that a pressure ratio of Ar to the total of Ne and Ar is in a range of 0.001 or greater and 0.05 or less.

With this configuration, it is possible to more appropriately minimize or prevent shift of an EIT signal due to a temperature variation in the gas cell.

### APPLICATION EXAMPLE 4

In the atomic oscillator according to the application example described above, it is preferable that an internal pressure of the gas cell is in a range of 80 Torr or higher and 150 Torr or lower.

With this configuration, it is possible to more appropriately minimize or prevent shift of an EIT signal due to a temperature variation in the gas cell.

### APPLICATION EXAMPLE 5

In the atomic oscillator according to the application example described above, it is preferable that the atomic oscillator includes a heating unit that heats the gas cell, and an internal temperature of the gas cell is set to be in a range of 50° C. or higher and 90° C. or lower.

When a temperature of the gas cell is set to be in this range, if a pressure ratio of Ar to the total of Ne and Ar is set to be in the range, it is possible to more considerably reduce a shift amount of an EIT signal.

### APPLICATION EXAMPLE 6

In the atomic oscillator according to the application example described above, it is preferable that a surface area of an inner wall of the gas cell is in a range of 0.06 cm² or more and 6 cm² or less.

As mentioned above, the invention is applied to the small-sized gas cell, and thus it is possible to more appropriately minimize or prevent shift of an EIT signal due to a temperature variation in the gas cell.

### APPLICATION EXAMPLE 7

This application example is directed to a frequency adjusting method of an atomic oscillator including a gas cell into which a metal atom, neon (Ne), and argon (Ar) are sealed, including: sealing a gas including Ne and Ar into the gas cell in a state in which a pressure ratio of Ar to the total of Ne and Ar is greater than 0 and less than 0.5.

With this configuration, it is possible to provide the atomic oscillator having a high accuracy reference frequency without being influenced by a temperature variation in the gas cell.

### APPLICATION EXAMPLE 8

This application example is directed to an electronic apparatus including the atomic oscillator according to the application example described above.

With this configuration, it is possible to provide an electronic apparatus with high reliability.

### APPLICATION EXAMPLE 9

This application example is directed to a moving object including the atomic oscillator according to the application example described above.

With this configuration, it is possible to provide a moving object with high reliability.

### BRIEF DESCRIPTION OF THE DRAWINGS

The invention will be described with reference to the accompanying drawings, wherein like numbers reference like elements.

FIG. 1 is a schematic diagram illustrating an atomic oscillator according to an embodiment of the invention.

FIG. 2 is a diagram illustrating an energy state of an alkali metal in a gas cell of the atomic oscillator illustrated in FIG. 1.

FIG. 3 is a graph illustrating a relationship between a frequency difference between two light beams emitted from a light source, and an intensity detected by a light detection unit, in the light source and the light detection unit of the atomic oscillator illustrated in FIG. 1.

FIG. 4 is a graph illustrating a relationship between a pressure ratio of Ar to the total of Ne and Ar and a temperature coefficient of an EIT signal.

FIG. 5 is a diagram illustrating a schematic configuration in a case where the atomic oscillator according to the embodiment of the invention is applied to a positioning system using a GPS satellite.

FIG. 6 is a perspective view illustrating a configuration of a moving object (automobile) including the atomic oscillator according to the embodiment of the invention.

### DESCRIPTION OF EXEMPLARY EMBODIMENTS

Hereinafter, an atomic oscillator, a frequency adjusting method of the atomic oscillator, an electronic apparatus, and a moving object according to an embodiment of the invention will be described with reference to the accompanying drawings.

### 1. Atomic Oscillator

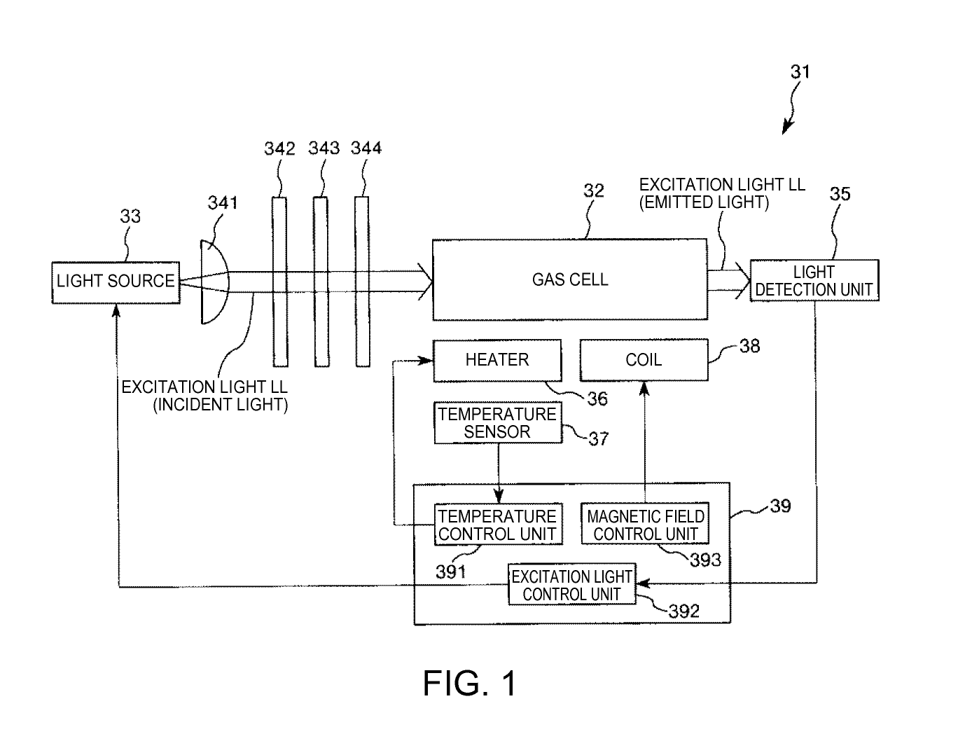

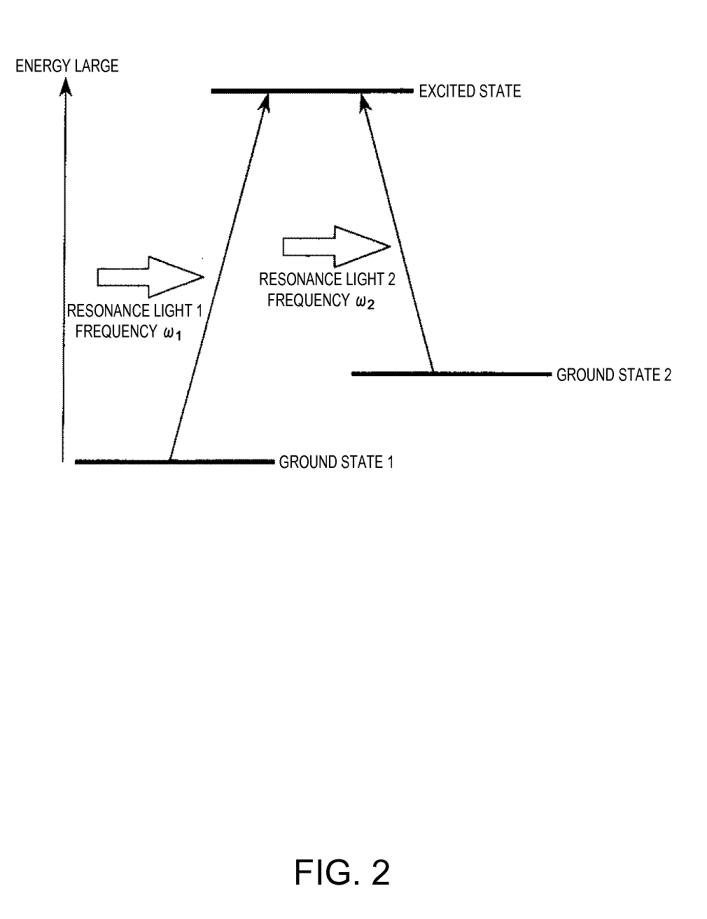

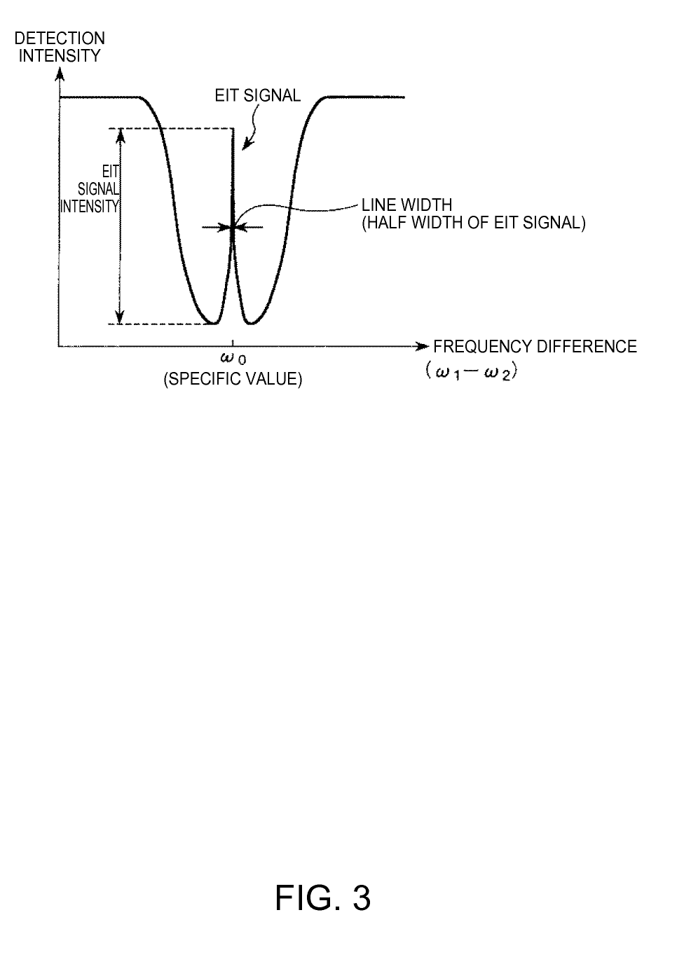

FIG. 1 is a schematic diagram illustrating an atomic oscillator according to an embodiment of the invention, FIG. 2 is a diagram illustrating an energy state of an alkali metal in a gas cell of the atomic oscillator illustrated in FIG. 1, and FIG. 3 is a graph illustrating a relationship between a frequency difference between two light beams emitted from a light source, and an intensity detected by a light detection unit in the light source and the light detection unit of the atomic oscillator illustrated in FIG. 1.

An atomic oscillator 31 oscillates a reference frequency on the basis of energy transition of an alkali metal atom such as gaseous rubidium, cesium or sodium.

In the present embodiment, the atomic oscillator 31 is an atomic oscillator using a quantum interference effect (also referred to as coherent population trapping (CPT)) caused by two types of resonance light beams with different wavelengths, and includes, as illustrated in FIG. 1, a gas cell (atomic cell) 32, a light source (light emitting unit) 33, optical components 341, 342, 343 and 344, a light detection unit (light reception unit) 35, a heater (heating unit) 36, a temperature sensor 37, a coil 38, and a controller 39.

First, a principle of the atomic oscillator 31 will be described briefly prior to description of a configuration of each unit included in the atomic oscillator 31 using the quantum interference effect.

In the atomic oscillator 31, an alkali metal (metal atom) such as gaseous rubidium, cesium or sodium is sealed into the gas cell 32.

The alkali metal has energy levels of a three-level system as illustrated in FIG. 2, and may take on three states including two ground states (ground states 1 and 2) with different energy levels and an excited state. Here, the ground state 1 is an energy state lower than the ground state 2.

When the above-described gaseous alkali metal is irradiated with the two types of resonance light beams 1 and 2 with different frequencies, light absorptance (light transmittance) of the resonance light beams 1 and 2 in the alkali metal varies depending on a difference (ω₁−ω₂) between a frequency ω₁ of the resonance light 1 and a frequency ω₂ of the resonance light 2.

In addition, when the difference (ω₁−ω₂) between the frequency ω₁ of the resonance light 1 and the frequency ω₂ of the resonance light 2 matches a frequency ω₀ corresponding to an energy difference between the ground state 1 and the ground state 2, excitation from the ground states 1 and 2 to the excited state stops, respectively. At this time, neither of the resonance light beams 1 and 2 is absorbed by the alkali metal, but both are transmitted therethrough. This phenomenon is called a CPT phenomenon or an electromagnetically induced transparency (EIT) phenomenon.

The light source 33 emits the above-described two types of light beams (the resonance light 1 and the resonance light 2) with different frequencies toward the gas cell 32.

Here, for example, if the frequency ω₁ of the resonance light 1 is fixed, and the frequency ω₂ of the resonance light 2 is changed, when the difference (ω₁−ω₂) between the frequency ω₁ of the resonance light 1 and the frequency ω₂ of the resonance light 2 matches a frequency ω₀ corresponding to an energy difference between the ground state 1 and the ground state 2, an intensity detected by the light detection unit 35 rapidly increases as illustrated in FIG. 3. This rapidly increasing signal is referred to as an EIT signal.

The EIT signal has an inherent value which is defined by the kind of alkali metal. Therefore, an atomic oscillator is implemented by using such an EIT signal as a reference.

In addition, in the atomic oscillator 31, not only the gaseous alkali metal (metal atom) but also a buffer gas such as nitrogen, helium, neon, argon, and krypton is sealed into the gas cell 32.

Here, the EIT signal has an inherent value defined depending on the kind of alkali metal, but a gaseous alkali metal atom undergoes thermal motion, and, due to the influence of the thermal motion, a spectral width of the EIT signal tends to increase. Therefore, if the buffer gas is sealed into the gas cell 32, the thermal motion can be reduced, and thus it is possible to appropriately minimize or prevent the increase of a spectral width of the EIT signal.

Hereinafter, each unit of the atomic oscillator 31 will be described in detail in order.

### Gas Cell

Not only an alkali metal (metal atom) such as gaseous lithium, sodium, potassium, rubidium, cesium or francium, but also a buffer gas such as nitrogen, helium, neon, argon, and krypton is sealed into the gas cell 32.

Although not illustrated, the gas cell 32 includes a main body portion having a columnar through hole, and a pair of window portions which blocks each of the openings of the through hole. Thus, an inner space in which the above-described alkali metal and buffer gas are sealed is formed, and the gaseous alkali metal and the buffer gas are sealed in the inner space.

Here, each window portion of the gas cell 32 transmits excitation light from the above-described light source 33 therethrough. In addition, one window portion is an incidence side window portion through which excitation light LL is incident to the gas cell 32, and the other window portion is an emission side window portion through which the excitation light LL is emitted from the gas cell 32.

A material forming the window portions of the gas cell 32 is not particularly limited as long as the material can transmit excitation light therethrough, but, may use, for example, a glass material and a quartz crystal.

In addition, a material forming the main body portion of the gas cell 32 is not particularly limited, and may use, for example, a metal material and a resin material, and may use a glass material and a quartz crystal in the same manner as in the window portions.

Further, each window portion is air-tightly joined to the main body portion. Thus, the inner space of the gas cell 32 can be formed as an air-tight space.

A method of joining the main body portion to each of the window portions in the gas cell 32 is not particularly limited as long as the method is defined according to such a forming material, but may use, for example, a joint method using an adhesive, a direct joint method, and an anodic joint method.

In addition, the gas cell 32 can be adjusted to a desired temperature by the heater 36, and is adjusted to a temperature of, for example, 50° C. or higher and 90° C. or lower.

### Light Source

The light source 33 has a function of emitting the excitation light LL for exciting an alkali metal atom in the gas cell 32.

More specifically, the light source 33 emits the above-described two types of light beams (the resonance light 1 and the resonance light 2) with different frequencies as the excitation light LL.

The resonance light 1 can excite the alkali metal in the gas cell 32 from the above-described ground state 1 to the excited state. On the other hand, the resonance light 2 can excite the alkali metal in the gas cell 32 from the above-described ground state 2 to the excited state.

The light source 33 is not particularly limited as long as the above-described excitation light can be emitted, but, for example, a semiconductor laser such as a vertical cavity surface emitting laser (VCSEL) may be used.

The light source 33 is connected to an excitation light control unit 392 of the controller 39 described later, and is controlled to be driven on the basis of a detection result of the light detection unit 35 (refer to FIG. 1).

In addition, a temperature of the light source 33 is adjusted to about 30° C. by a temperature adjustment element (a heating resistor, a Peltier element, or the like) (not illustrated).

### Optical Components

The plurality of optical components 341, 342, 343 and 344 are provided on an axis of the excitation light LL between the light source 33 and the gas cell 32.

In the present embodiment, the optical component 341, the optical component 342, the optical component 343, and the optical component 344 are disposed in this order from the light source 33 side to the gas cell 32 side.

The optical component 341 is a lens. Accordingly, the excitation light LL can be applied to the gas cell 32 without any waste.

In addition, the optical component 341 has a function of converting the excitation light LL into parallel light. Thus, it is possible to easily and reliably prevent the excitation light LL from being reflected at an inner wall of the gas cell 32. For this reason, resonance of the excitation light can be suitably caused in the gas cell 32, and, as a result, an oscillation characteristic of the atomic oscillator 31 can be improved.

The optical component 342 is a polarization plate. Thus, polarization of the excitation light LL from the light source 33 can be adjusted in a predetermined direction.

The optical component 343 is a dimming filter (ND filter). Thus, an intensity of the excitation light LL incident to the gas cell 32 can be adjusted (reduced). For this reason, even in a case where an output level of the light source 33 is high, the excitation light incident to the gas cell 32 can be adjusted to a desired light amount. In the present embodiment, an intensity of the excitation light LL which has passed through the optical component 342 and has polarization in a predetermined direction is adjusted by the optical component 343.

The optical component 344 is a λ/4 wavelength plate. Thus, the excitation light LL from the light source 33 can be converted from linearly polarized light into circularly polarized light (right-handed circularly polarized light or left-handed circularly polarized light).

As described later, in a state in which the alkali metal atoms in the gas cell 32 are Zeeman-split by a magnetic field of the coil 38, if linearly polarized excitation light is applied to the alkali metal atoms, the alkali metal atoms are uniformly distributed to and are present in a plurality of levels in which the atoms are Zeeman-split due to an interaction between the excitation light and the alkali metal atoms. As a result, since the number of alkali metal atoms with a desired energy level becomes less than the number of alkali metal atoms with other energy levels, the number of atoms showing a desired EIT phenomenon is reduced, thus an intensity of a desired EIT signal is reduced, and, as a result, an oscillation characteristic of the atomic oscillator 31 deteriorates.

In contrast, as described later, in a state in which the alkali metal atoms in the gas cell 32 are Zeeman-split by a magnetic field of the coil 38, if circularly polarized excitation light is applied to the alkali metal atoms, the number of alkali metal atoms with a desired energy level can be made relatively larger than the number of alkali metal atoms with other energy levels among a plurality of levels in which the alkali metal atoms are Zeeman-split. For this reason, the number of atoms showing a desired EIT phenomenon is increased, thus an intensity of a desired EIT signal is also increased, and, as a result, an oscillation characteristic of the atomic oscillator 31 can be improved.

### Light Detection Unit

The light detection unit 35 has a function of detecting an intensity of the excitation light LL (the resonance light beams 1 and 2) which has been transmitted through the gas cell 32. In other words, the light detection unit 35 has a function of detecting an EIT signal observed when the frequency difference (ω₁−ω₂) matches a frequency ω₀.

The light detection unit 35 is not particularly limited as long as the excitation light can be detected, but, for example, a light detector (light receiving element) such as a solar cell or a photodiode may be used.

The light detection unit 35 is connected to the excitation light control unit 392 of the controller 39 described later (refer to FIG. 1).

### Heater

The heater 36 has a function of heating the above-described gas cell 32 (more specifically, the alkali metal and the buffer gas in the gas cell 32). Thus, the alkali metal in the gas cell 32 can be maintained in a gaseous phase.

The heater 36 generates heat due to conduction, and is formed by, for example, heating resistors (not illustrated) provided on an outer surface of the gas cell 32.

Here, the heating resistors are provided at the respective window portions of the gas cell 32. Thus, the alkali metal atoms can be prevented from being condensed on the window portions of the gas cell 32. As a result, an oscillation characteristic can be made favorable for a long period of time.

These heating resistors are made of a material which transmits excitation light therethrough, specifically, a transparent electrode material such as an oxide, for example, indium tin oxide (ITO), indium zinc oxide (IZO), In₃O₃, SnO₂, Sb-containing SnO₂, or Al-containing ZnO.

In addition, the heating resistors may be formed by using, for example, chemical vapor deposition (CVD) such as plasma CVD or thermal CVD, dry plating such as vacuum deposition, a sol/gel method, or the like.

In addition, the heater 36 is not limited to the above-described form as long as the gas cell 32 can be heated, and may not be in contact with the gas cell 32. Furthermore, the gas cell 32 may be heated by using a Peltier element instead of the heater 36 or along with the heater 36.

The heater 36 is electrically connected to a temperature control unit 391 of the controller 39 described later so as to be conducted (refer to FIG. 1).

### Temperature Sensor

The temperature sensor 37 detects a temperature of the heater 36 or the gas cell 32. In addition, a heating amount of the above-described heater 36 is controlled on the basis of a detection result from the temperature sensor 37. Thus, the inside of the gas cell 32, more specifically, the alkali metal atom and the buffer gas can be maintained at a desired temperature.

In addition, a position where the temperature sensor 37 is installed is not particularly limited, and, for example, may be installed on the heater 36, and may be installed on the outer surface of the gas cell 32.

The temperature sensor 37 is not particularly limited, and may use well-known temperature sensors such as a thermistor and a thermocouple.

The temperature sensor 37 is electrically connected to the temperature control unit 391 of the controller 39 described later via wiring (not illustrated) (refer to FIG. 1).

### Coil

The coil 38 (magnetic field generation unit) has a function of generating a magnetic field in a direction along the axis of the excitation light LL in the gas cell 32. Thus, gaps between other degenerated energy levels of the alkali metal are enlarged by the Zeeman splitting, and thus resolution can be improved. As a result, it is possible to increase accuracy of an oscillation frequency of the atomic oscillator 31.

The coil 38 may use, for example, Helmholtz coils which are disposed with the gas cell 32 interposed therebetween, or a solenoid coil disposed so as to cover the gas cell 32.

In addition, a magnetic field generated by the coil 38 may be either a DC magnetic field or an AC magnetic field, and may be a magnetic field in which the DC magnetic field and the AC magnetic field overlap each other.

The coil 38 is connected to a magnetic field control unit 393 of the controller 39 described later, and is controlled to be operated (refer to FIG. 1).

### Controller

The controller 39 illustrated in FIG. 1 has a function of controlling each of the light source 33, the heater 36, and the coil 38.

The controller 39 includes the excitation light control unit 392 which controls frequencies of the resonance light beams 1 and 2 from the light source 33, the temperature control unit 391 which controls a temperature of the alkali metal in the gas cell 32, and the magnetic field control unit 393 which controls a magnetic field applied to the gas cell 32.

The excitation light control unit 392 controls frequencies of the resonance light beams 1 and 2 which are emitted from the light source 33 on the basis of a detection result from the above-described light detection unit 35. More specifically, the excitation light control unit 392 controls frequencies of the resonance light beams 1 and 2 emitted from the light source 33 so that (ω₁−ω₂) detected by the light detection unit 35 becomes the inherent frequency ω₀ of the alkali metal. In addition, the excitation light control unit 392 controls central frequencies of the resonance light beams 1 and 2 emitted from the light source 33.

Further, the temperature control unit 391 controls a current which flows to the heater 36 on the basis of a detection result from the temperature sensor 37. Thus, the gas cell 32 can be maintained in a desired temperature range. Here, the temperature sensor 37 forms a temperature detection unit which detects a temperature of the gas cell 32.

Further, the magnetic field control unit 393 controls a current which flows to the coil 38 so as to make a magnetic field generated by the coil 38 constant.

The controller 39 is provided in, for example, an IC chip mounted on a board.

In addition, the controller 39 is electrically connected to an oscillation circuit (not illustrated), and the oscillation circuit oscillates a clock signal on the basis of the above-described EIT signal.

However, in the atomic oscillator 31 with this configuration, the gas cell 32 can be maintained in a desired temperature range by the temperature control unit 391 controlling a current which flows to the heater 36, but a temperature naturally varies in the gas cell 32 in this temperature range. For this reason, as described above, if buffer gas is sealed into the gas cell 32, a temperature characteristic appears in which an EIT signal is shifted due to the temperature variation in the gas cell.

Therefore, in the related art, in order to prevent the EIT signal from being shifted, a method is employed in which two kinds of buffer gases which cancel out the mutual temperature characteristics in which an EIT signal is shifted are mixed at a predetermined mixture ratio in the gas cell. Specifically, JP-A-2010-245805 discloses a method in which Ne and Ar as buffer gases are mixed at a mixture ratio (pressure ratio) of 1:1 in the gas cell on the basis of the fact that, in a case where a Cs gas is sealed into a gas cell 32 as an alkali metal gas, if Ne is sealed alone as a buffer gas, an EIT signal is shifted with a temperature characteristic of +3 Hz/° C., and if Ar is sealed alone as a buffer gas, an EIT signal is shifted with a temperature characteristic of −3 Hz/° C.

However, according to another examination conducted by the present inventor, if each of Ne and Ar is sealed alone as a buffer gas, an EIT signal is shifted as described above, but it has been found that a deviation occurs in the temperature characteristics in which the EIT signal is shifted if a mixed gas in which Ne and Ar are mixed is mixed at a pressure ratio of 1:1 as a buffer gas.

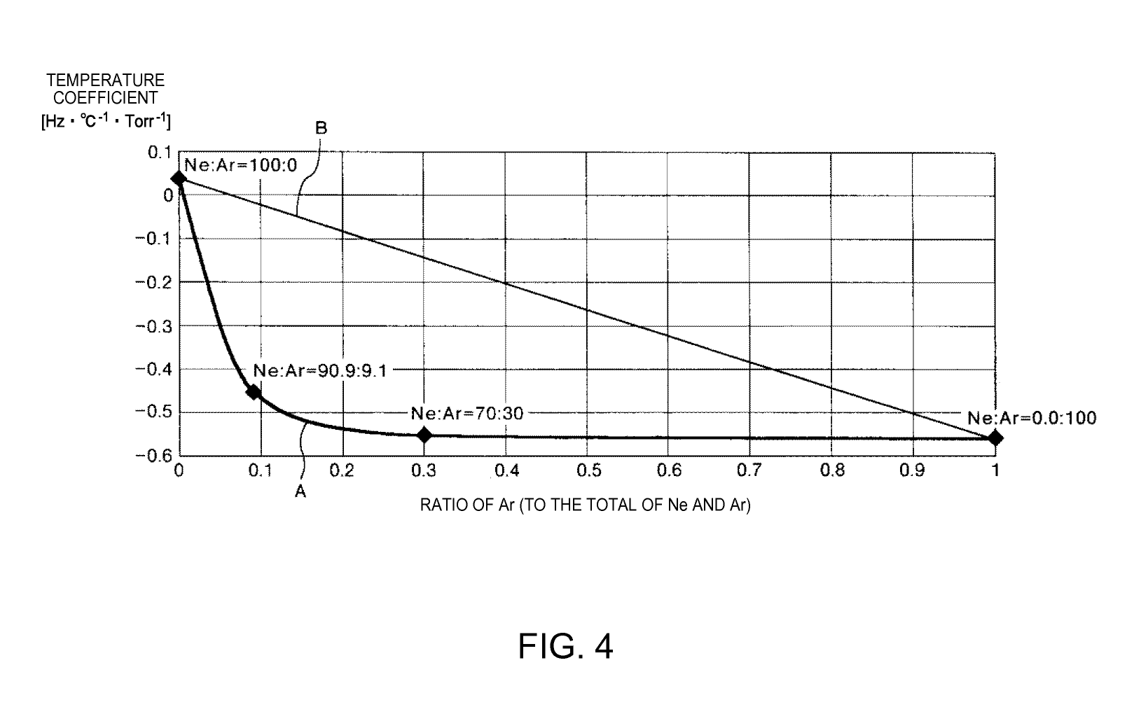

More specifically, it has been found that, in a case where a Cs gas as an alkali metal gas is sealed into the gas cell (a surface area of an inner wall: 2.06 cm²) 32, a partial pressure applied to both of Ne and Ar is 1 Torr, and a mixture of Ne and Ar as buffer gases is sealed into the gas cell 32, if a pressure ratio (mixture ratio) of Ar to Ne is changed, a temperature characteristic in which an EIT signal is shifted, that is, a temperature coefficient of the EIT signal is changed as illustrated in FIG. 4.

As is clear from FIG. 4, a graph A indicating a relationship between a pressure ratio of Ar to the total of Ne and Ar and a temperature coefficient of the EIT signal is not linear but non-linear, and is located in a region lower than a straight line B which connects a point where Ne:Ar indicating a pressure ratio of Ar to the total of Ne and Ar is 100:0 to a point at 0:100.

For this reason, since a pressure ratio of Ne is not sufficient if a pressure ratio of Ne to Ar sealed into the gas cell 32 is only 1:1 (a pressure ratio of Ar to the total of Ne and Ar is 0.5) as in the related art, in the present embodiment, a pressure ratio of Ne is set to be greater than a pressure ratio of Ar. In other words, a pressure ratio of Ar to the total of Ne and Ar is set to be greater than 0 and less than 0.5. Thus, it is possible to appropriately minimize or prevent shift of an EIT signal due to a temperature variation in the gas cell 32. Therefore, it is possible to provide the atomic oscillator 31 having a high accuracy reference frequency without being influenced by a temperature variation in the gas cell 32.

In addition, the gas cell 32 satisfying this relationship can be obtained by sealing a buffer gas including Ne and Ar into the gas cell 32 at a sealing pressure in which a pressure ratio of Ar to the total of Ne and Ar is set to be greater than 0 and less than 0.5 (a frequency adjusting method of an atomic oscillator according to the embodiment of the invention).

Further, a pressure ratio of Ar to the total of Ne and Ar may be set to be greater than 0 and less than 0.5, but preferably, set to be 0.001 or greater and 0.05 or less, more preferably, set to be 0.001 or greater and 0.004 or less, and, most preferably, set to 0.003. Thus, it is possible to appropriately minimize or prevent shift of an EIT signal due to a temperature variation in the gas cell 32. In other words, a temperature coefficient of an EIT signal can be approximated to 0.

Furthermore, in relation to the relationship between a pressure ratio of Ar to the total of Ne and Ar and a temperature coefficient of an EIT signal as illustrated in FIG. 4, any one of lithium, sodium, potassium, rubidium, cesium, and francium may be included as an alkali metal sealed into the gas cell 32, but at least one species of rubidium and cesium is preferably included, and cesium is more preferably included. When such metal is included as an alkali metal, if a pressure ratio of Ar to the total of Ne and Ar is set to be in the range, it is possible to more appropriately minimize or prevent shift of an EIT signal due to a temperature variation in the gas cell 32.

In addition, when a pressure ratio of Ar to the total of Ne and Ar is set to be in the range, an internal pressure of the gas cell 32 is preferably 80 Torr or higher and 150 Torr or lower, and, more preferably, 100 Torr or higher and 120 Torr or lower. Thus, it is possible to more appropriately minimize or prevent shift of an EIT signal due to a temperature variation in the gas cell 32.

Further, as described above, a temperature of the gas cell 32 is adjusted to, for example, 50° C. or higher and 90° C. or lower by the heater 36, but is preferably adjusted to about 70° C. When a temperature of the gas cell 32 is set to be in this range, if a pressure ratio of Ar to the total of Ne and Ar is set to be in the range, it is possible to more considerably reduce a shift amount of an EIT signal.

Furthermore, a surface area of the inner wall of the gas cell 32 is preferably 0.06 cm² or more and 6.0 cm² or less, and, more preferably, 1.0 cm² or more and 4.0 cm² or less. As mentioned above, according to the small-sized gas cell 32 of the present embodiment of the invention, it is possible to more appropriately minimize or prevent shift of an EIT signal due to a temperature variation in the gas cell 32. In addition, the remarkable effect achieved by applying the invention to the small-sized gas cell 32 is believed to result from the inner wall surface of the gas cell 32 contributing to absorption of light incident to the gas cell 32.

Moreover, in the present embodiment, as the atomic oscillator 31, the atomic oscillator 31 using a quantum interference effect (also referred to as coherent population trapping (CPT)) which is caused by two kinds of light beams with different wavelengths has been described, but the atomic oscillator 31 may be an atomic oscillator using a double resonance phenomenon caused by light and microwaves. However, the atomic oscillator 31 which oscillates by using the quantum interference effect can be made far more small-sized than an atomic oscillator using the double resonance phenomenon. Therefore, as described above, in the present embodiment of the invention, since a shift amount of the EIT signal is considerably reduced when the gas cell 32 is made small-sized, the invention is preferably applied to the atomic oscillator 31 which oscillates by using the quantum interference effect.

### 2. Electronic Apparatus

The atomic oscillator according to the embodiment of the invention as described above may be incorporated into various electronic apparatuses. These electronic apparatuses including the atomic oscillator according to the embodiment of the invention have high reliability.

Hereinafter, an example of an electronic apparatus including the atomic oscillator according to the embodiment of the invention will be described.

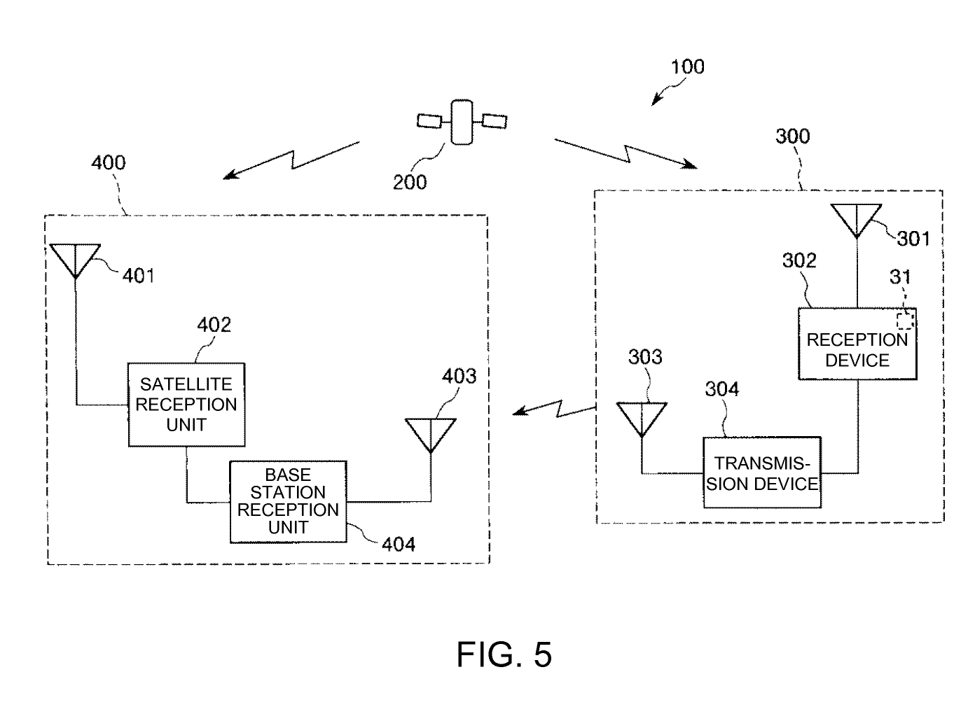

FIG. 5 is a diagram illustrating a schematic configuration in a case where the atomic oscillator according to the embodiment of the invention is used in a positioning system using a GPS satellite.

A positioning system 100 illustrated in FIG. 5 includes a GPS satellite 200, a base station apparatus 300, and a GPS reception apparatus 400.

The GPS satellite 200 transmits positioning information (GPS signal).

The base station apparatus 300 includes, for example, a reception device 302 which receives the positioning information from the GPS satellite 200 via an antenna 301 which is installed at an electronic reference point (GPS Observation Network of Geographical Survey Institute), and a transmission device 304 which transmits the positioning information received by the reception device 302 via an antenna 303.

Here, the reception device 302 is an electronic apparatus which includes the atomic oscillator 31 according to the embodiment of the invention as a reference frequency oscillation source. The reception device 302 has high reliability. In addition, the positioning information received by the reception device 302 is transmitted by the transmission device 304 in real time.

The GPS reception apparatus 400 includes a satellite reception unit 402 which receives the positioning information from the GPS satellite 200 via an antenna 401, and a base station reception unit 404 which receives the positioning information from the base station apparatus 300 via an antenna 403.

### 3. Moving Object

The atomic oscillator according to the embodiment of the invention may be incorporated into various moving objects. These moving objects including the atomic oscillator according to the embodiment of the invention have high reliability.

Hereinafter, an example of a moving object according to the embodiment of the invention will be described.

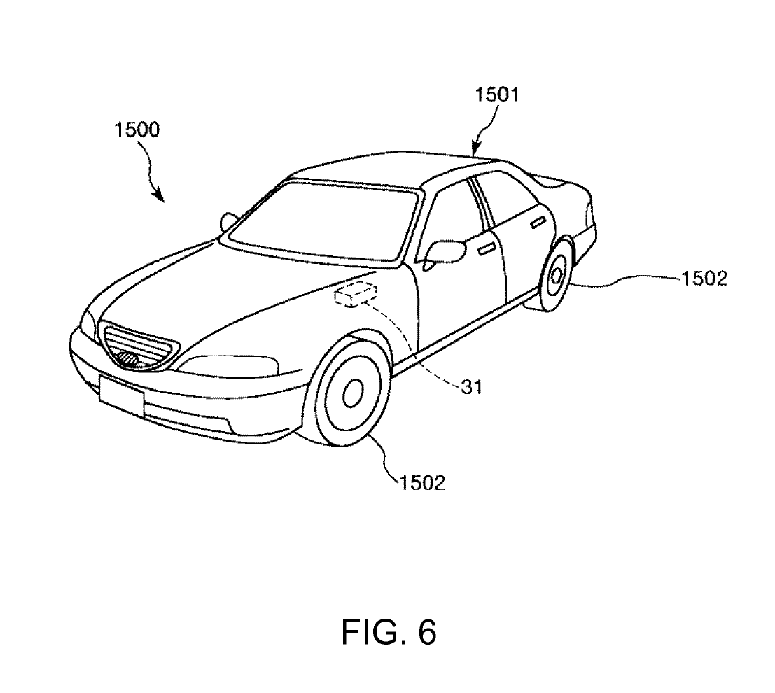

FIG. 6 is a perspective view illustrating a configuration of a moving object (automobile) including the atomic oscillator according to the embodiment of the invention.

A moving object 1500 illustrated in FIG. 6 has a car body 1501 and four wheels 1502, and the wheels 1502 are rotated by a power source (engine) (not illustrated) provided in the car body 1501. The atomic oscillator 31 is built in the moving object 1500. In addition, for example, a controller (not illustrated) controls driving of the power source on the basis of an oscillation signal from the atomic oscillator 31.

In addition, electronic apparatuses or moving objects having the atomic oscillator according to the embodiment of the invention are not limited thereto, and may be applied to, for example, a mobile phone, a digital still camera, an ink jet type ejection apparatus (for example, an ink jet printer), a personal computer (a mobile type personal computer or a laptop type personal computer), a television, a video camera, a video tape recorder, a car navigation apparatus, a pager, an electronic organizer (including a communication function), an electronic dictionary, an electronic calculator, an electronic gaming machine, a wordprocessor, a workstation, a videophone, a security television monitor, an electronic binocular, a POS terminal, a medical apparatus (for example, an electronic thermometer, a sphygmomanometer, a blood glucose monitoring system, an electrocardiographic apparatus, an ultrasonic diagnostic apparatus, or an electronic endoscope), a fish-finder, various measurement apparatuses, meters and gauges (for example, meters and gauges of vehicles, aircrafts, and ships), a flight simulator, a terrestrial digital broadcast, and a mobile phone base station.

As mentioned above, the atomic oscillator, the frequency adjusting method of the atomic oscillator, the electronic apparatus, and the moving object according to the embodiment of the invention have been described with reference to the drawings, but the invention is not limited thereto.

In addition, in the atomic oscillator, the frequency adjusting method of the atomic oscillator, the electronic apparatus, and the moving object according to the embodiment of the invention, a configuration of each unit may be replaced with any configuration meeting the same function, and any configuration may be added thereto.

The entire disclosure of Japanese Patent Application No. 2013-205753, filed Sep. 30, 2013 is expressly incorporated by reference herein.

What is claimed is:

1. An atomic oscillator comprising:
a gas cell into which a metal atom and a buffer gas are sealed;
a light source that emits light for exciting the metal atom in the gas cell; and
a light reception unit that detects the light which has been transmitted through the gas cell,
wherein the buffer gas includes neon (Ne) and argon (Ar), and a pressure ratio of Ar to the total of Ne and Ar is greater than 0 and less than 0.5.

2. The atomic oscillator according to claim 1, wherein the metal atom includes cesium (Cs).

3. The atomic oscillator according to claim 1, wherein a pressure ratio of Ar to the total of Ne and Ar is in a range of 0.001 or greater and 0.05 or less.

4. The atomic oscillator according to claim 1, wherein an internal pressure of the gas cell is in a range of 80 Torr or higher and 150 Torr or lower.

5. The atomic oscillator according to claim 1, further comprising:
a heating unit that heats the gas cell,
wherein an internal temperature of the gas cell is set to be in a range of 50° C. or higher and 90° C. or lower.

6. The atomic oscillator according to claim 1, wherein a surface area of an inner wall of the gas cell is in a range of 0.06 cm² or more and 6 cm² or less.

7. A frequency adjusting method of an atomic oscillator including a gas cell into which a metal atom, neon (Ne), and argon (Ar) are sealed, comprising:
sealing a gas including Ne and Ar into the gas cell in a state in which a pressure ratio of Ar to the total of Ne and Ar is greater than 0 and less than 0.5.

8. An electronic apparatus comprising the atomic oscillator according to claim 1.

9. A moving object comprising the atomic oscillator according to claim 1.
